(19) United States
(12) Patent Application Publication
(10) Pub. No.: US 2003/0047282 A1
(43) Pub. Date: Mar. 13, 2003

(54) Surface processing apparatus

(76) Inventors: Yasumi Sago, Tokyo (JP); Masayoshi Ikeda, Tokyo (JP); Kazuaki Kaneko, Tokyo (JP); Daisuke Kondo, Tokyo (JP); Osamu Morita, Tokyo (JP)

Correspondence Address: Platon N. Mandros, BURNS, DOANE, SWECKER & MATHIS, L.L.P., P.O. Box 1404, Alexandria, VA, 22313-1404, US

(21) Appl. No.: 10/234,540

(22) Filed: Sep. 5, 2002

(30) Foreign Application Priority Data
Sep. 10, 2001 (JP) 2001-273027

(51) Int. Cl. C23F 1/00; H01L 21/306; C23C 16/00

(52) U.S. Cl. 156/345.34; 118/715; 156/345.33

(57) ABSTRACT

The invention is to realize a gas ejection mechanism, which makes it possible to form a uniform gas flow and to control the temperature and its distribution over a gas plate, and thereby to provide a surface processing apparatus which can continuously carry out uniform processing. A surface processing apparatus of this invention comprises: a process chamber in which a substrate holding mechanism and a gas ejection mechanism are arranged to face each other; an exhaust means; and a gas supply means; wherein a gas distribution mechanism, a cooling or the heating mechanism provided with a coolant channel or a heater to cool or heat a gas plate and a number of gas passages, and the gas plate having a number of gas outlets communicated with the gas passages are arranged in that order from the upper stream to construct the gas ejection mechanism, and wherein the gas plate is fixed to the cooling or heating mechanism with a clamping member or with an electrostatic chucking mechanism. A second gas distribution mechanism may be installed between the gas plate and the cooling or heating mechanism so as to form gas outlets under the coolant channel.

### BACKGROUND OF THE INVENTION

1. Field of the Invention

The present invention relates to a surface processing apparatus and, more particularly, to a surface processing apparatus with a gas ejection mechanism, which has an excellent uniformity in temperature over the entire surface, and suppresses the temperature change during processing.

2. Related Art

The surface processing carried out using gas, such as a dry etching and CVD, is greatly influenced by the temperature of a substrate and members surrounding the substrate, and the flow of gas. Therefore, in order to carry out stable processing continuously, a gas ejection mechanism which is controlled to make gas uniformly flow and is maintained at a prescribed temperature is required as well as a mechanism to control the substrate temperature.

A conventional gas ejection mechanism is explained with reference to FIG. 11. FIG. 11 is a cross sectional view showing the configuration of a dry etching apparatus disclosed in JP7-335635A.

As shown in the drawing, a gas ejection mechanism 101, which serves as an opposite electrode, is arranged facing a substrate 105 in a process chamber 100. The opposite electrode 101, composed of a gas plate 104 having a number of gas outlets 104a, a support plate holding this gas plate, and a cooling jacket 102 having a coolant channel 106 inside, is fixed to process chamber 100 through an insulator 108. Gas passages 102a and 103a are respectively provided in cooling jacket 102 and support plate 103 so that the passages are communicated with gas outlets 104a of the gas plate. The gas plate 104 is fixed with, for example, brazing on support plate 103 of about 10 mm in thickness. The support plate is further fixed on cooling jacket 102 with bolts 109. In addition, gas distribution grooves 103b and 104b are formed perpendicularly on the contact surfaces of the support plate and the gas plate to easily align gas outlets 104a and gas passages 103a. The gas that is introduced through a gas introduction pipe 110 is distributed in a gas passage 107 and then is ejected into process chamber 100 from gas outlets 104a through gas passages 102a, 103a and gas distribution grooves 103b, 104b.

The cooling water channel 106 is formed in cooling jacket 102. The cooling water is supplied from a cooling water supply pipe 106a and drained into discharge pipe 106b. The gas plate exposed to plasma is indirectly cooled through the heat transfer between the cooling jacket and support plate and then between the support plate and the gas plate. Thus, the temperature rise of gas plate is prevented to carry out uniform etching processing.

During the research and developments of the high-speed etching technique for ultra-fine patterns, the present inventors studied the relations between the configuration of the gas ejection mechanism and the accuracy of etched pattern, and found that more uniform gas flow and more precise control of gas plate temperature are required in order to carry out finer pattern etching. However, it was practically impossible to simultaneously satisfy both conditions as long as the gas ejection mechanism shown in FIG. 11 is employed.

That is, since the gas plate was indirectly cooled through the support plate as shown in FIG. 11, the capacity to cool the gas plate was insufficient for some processing conditions, and the etching uniformity was decreased as the etching pattern became finer. Then, the present inventors enlarged the cooling water channel in order to improve cooling capacity; however, the density of gas outlets had to be reduced, which decreased the uniformity of gas flow distribution and resulted in insufficient etching uniformity.

Furthermore, when processing is repeatedly and continuously carried out, the desired etching characteristic cannot be obtained during a period after the processing starts. That is, the processing is made in vain during this period. This problem becomes more serious as the etching pattern becomes finer. In the case of, e.g., 0.13 μm pattern, the desired characteristic was not obtained for first fifteen to twenty wafers after the processing started.

The gas ejection mechanism of FIG. 11 is constructed by fixing the gas plate on the support plate with, e.g., brazing. Therefore, the surface of gas plate is easily contaminated to deteriorate the etching characteristic. In addition, it is not easy to fix the gas plate without clogging gas outlets. This work is complicated and requires high skill and time. The method of fixing the gas plate by fastening parts of gas plate with bolts is also disclosed. However, sufficient cooling effect could not be obtained and the gas plate was difficult to be evenly pressed, resulting in large non-uniform temperature distribution. Furthermore, This method is disadvantageous in that the gas plate is easy to break down by heat during processing.

Furthermore, although the gas plate is preferably made from scavenger materials in order to remove the activated species which reacts with photoresist, such materials as Si or SiO2 has a disadvantage of being easily broken due to thermal hysteresis if a complicated shape such as groove is formed.

The problems as to the gas flow distribution and the temperature distribution of the gas plate are also observed in the cases of other surface processing apparatuses. For example, if the gas ejection mechanism of thermal CVD apparatus has a non-uniform temperature distribution, the decomposition of gas and film deposition occurs more rapidly at higher temperature portions. The deposited film will peel off and cause the generation of particles. In addition, the film deposition rate varies with the position on the substrate depending on the temperature distribution of the gas plate under certain circumstances.

### SUMMARY OF THE INVENTION

The present inventors have further made examinations especially on etching apparatuses based on above-mentioned information. That is, the inventors have earnestly studied the relationship among the structure of the gas ejection mechanism, the arrangement of its constituting members, etching characteristic and reproducibility, and finally completed this invention.

The object of this invention is to realize a gas ejection mechanism, which makes it possible to form a uniform gas flow distribution and to control the temperature and its distribution of a gas plate, and then to provide a surface processing apparatus, which can continuously carry out uniform processing.

A first surface processing apparatus of this invention comprises: a process chamber in which a substrate holding mechanism holding a substrate and a gas ejection mechanism are arranged to face each other; an exhaust means for exhausting the inside of said process chamber; and a gas supply means for supplying a gas to said gas ejection mechanism; to process the substrate with the gas introduced into said process chamber through said gas ejection mechanism,

wherein a gas distribution mechanism communicate with said gas supply means, a cooling or the heating mechanism provided with a coolant channel or a heater to cool or heat a gas plate and a number of gas passages, and said gas plate having a number of gas outlets communicated with said number of gas passages are arranged from the upper stream in said gas ejection mechanism,

and wherein said gas plate is fixed to said cooling or heating mechanism with a clamping member which clamps the periphery of said gas plate or with an electrostatic chucking mechanism.

Thus, a uniform gas flow distribution can be formed by arranging a gas ejection mechanism, a cooling or a heating mechanism, and a gas plate in this order from the upper stream to construct a gas ejection mechanism. In addition, since the gas plate is in direct contact with the heating or cooling mechanism and evenly pressed by an electrostatic chucking mechanism or a clamping mechanism, the efficiency to cool or heat the gas plate and its uniformity are remarkably improved, and therefore the gas plate surface can be maintained at a predetermined temperature uniformly over the whole surface.

A second surface processing apparatus of this invention comprises: a process chamber in which a substrate holding mechanism holding a substrate and a gas ejection mechanism are arranged to face each other; an exhaust means for exhausting the inside of said process chamber; and a gas supply means for supplying a gas to the said gas ejection mechanism; to process the substrate with the gas introduced into said process chamber through said gas ejection mechanism,

wherein a first gas distribution mechanism communicated with said gas supply means, a cooling or a heating mechanism provided with a coolant channel or a heater to cool or heat a gas plate and a number of gas passages, a second gas distribution mechanism, and said gas plate having a number of gas outlets which are more than said gas passages are arranged in this order from the upper stream to construct said gas ejection mechanism, and said gas passages are communicated with said gas outlets through said second gas distribution mechanism, and

wherein said gas plate is fixed to said cooling or heating mechanism with a clamping member which clamps the periphery of said gas plate or with an electrostatic chucking mechanism.

By arranging a second gas distribution mechanism between a gas plate and a cooling or a heating mechanism, and by branching gas passages of the cooling or heating mechanism, the gas outlets can be formed just under, e.g., a coolant channel. That is, even if a coolant channel with large cooling capacity is provided, a large number of gas outlets can be formed with high density, which is inevitable for forming a uniform gas flow distribution. Consequently, as in the case of the first surface processing apparatus mentioned above, it becomes possible to form uniform gas flow distribution, to prevent the temperature rise of the gas plate and to improve the temperature uniformity. Thus, uniform processing can be made stably and repeatedly.

In this invention, the second gas distribution mechanism is preferable to be a space with a height of 0.1 mm or less and the pressure in this space is set to 100 Pa or higher. Thereby, the heat transfer between the cooling or heating mechanism and the gas plate with gas is increased, which improves the cooling efficiency. Furthermore, the diameter of gas outlet of 0.01-1 mm is desirable, and that of 0.2 mm or less is preferable, which can control gas flow distribution more uniformly and eject gas uniformly over the whole substrate.

The surface processing apparatus of this invention is preferably applied to a plasma processing apparatus, which carries out processing by supplying high frequency electric power to the gas ejection mechanism to generate plasma.

Moreover, the efficiency for cooling or heating the gas plate, and the temperature uniformity of the gas plate are further improved by preparing the ruggedness on both surfaces of the gas plate and the cooling or heating mechanism or both surfaces of the gas plate and the second gas distribution mechanism so that the ruggedness of both surfaces is engaged with each other.

A flexible heat conductive sheet may be sandwiched between the gas plate and the cooling or heating mechanism or between the gas plate and the second gas distribution mechanism. The heat conductive sheet enters into the microscopic roughness, which improves the heat transfer between them.

As a material of the gas plate, non-metal material such as Si, SiO2, SiC, carbon, or the like is preferably used, especially for an etching apparatus.

### BRIEF DESCRIPTION OF THE DRAWINGS

FIG. 1 is a cross-sectional view showing the first embodiment of this invention.

FIG. 2 is a cross-sectional view showing an example of gas plate clamping mechanism of this invention.

FIGS. 3-5, 7-8 show a cross-sectional view of an example of gas ejection mechanism.

FIG. 6 is a cross-sectional view showing the second embodiment of this invention.

FIG. 9 is a cross-sectional view showing the third embodiment of this invention.

FIG. 10 is a sectional-sectional view showing the fourth embodiment of this invention. FIG. 11 is a cross-sectional view showing a gas ejection mechanism of the conventional etching apparatus.

In these drawings, numeral 1 denotes a process chamber; 2, a gas ejection mechanisms (opposite electrode); 3, a frame member; 4, a gas distribution plate; 5, cooling jacket; 5a, a gas passage; 5b, a coolant channel: 6, a gas plate;

6a, a gas outlet; 7, a substrate holding electrode (substrate holding mechanism); 8, a coolant channel; 9, an electrostatic chuck; 10, a gas introduction pipe; 11, a second distribution mechanism; 12a, 12b, an insulator; 13, a valve; 14,15; a high frequency power source; 17, a DC power source; 19, an ejector pin; 21, a bellows; 22, a gas supply system; 24, an annular fastener; 25, a screw; 26, heat conductive sheet; 27, an electrostatic chuck; 27a, a dipole electrode; 29, ruggedness; 31, a gas branch groove(passage); 32, a heating mechanism; 32b, 33,a heater; 40, substrate; 41, 43 O-ring; 42, passage; 44, connecting member, 45, pressure gauge; and 46, insulator.

### DETAILED DESCRIPTION OF THE INVENTION

The preferred embodiments of this invention will be explained with reference to drawings.

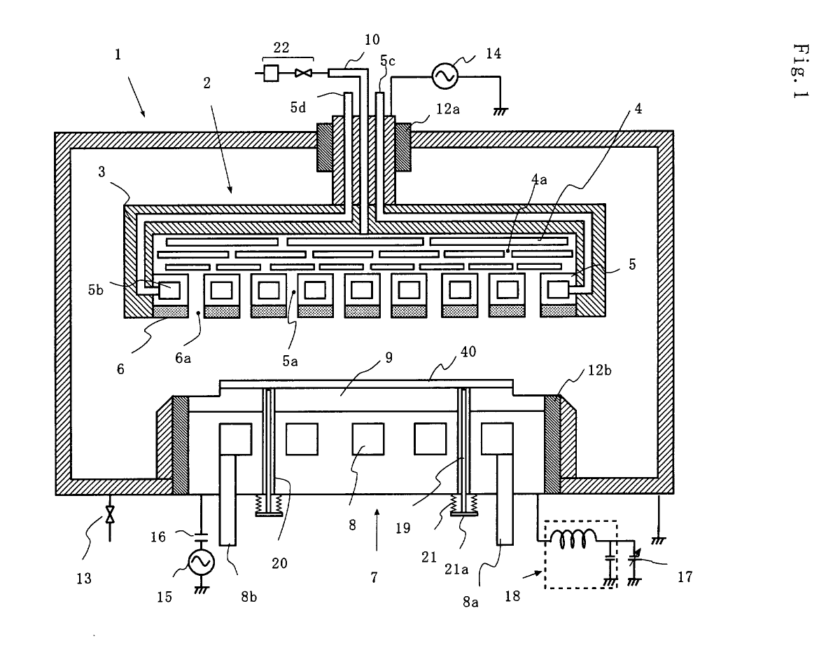

An etching apparatus, one of surface processing apparatuses of this invention, is explained below as the first embodiment. FIG. 1 is a cross sectional view showing an example of etching apparatuses of this invention, which carries out the etching processing on a substrate by ejecting a process gas toward the substrate from a gas ejection mechanism and supplying high frequency electric power to the gas ejection mechanism to generate plasma. That is, in this embodiment, the gas ejection mechanism plays a role of an opposite electrode, which is arranged facing a substrate holding electrode.

As shown in FIG. 1, opposite electrode (gas ejection mechanism) 2 and substrate holding electrode (substrate holding mechanism) 7 which holds a substrate 40 are arranged facing each other in a process chamber 1, and are fixed to the process chamber 1 through insulators 12a and 12b, respectively. The process chamber is connected with an exhaust means (not illustrated) through a valve 13. The opposite electrode 2 is connected with a first high frequency power source 14 for generating plasma as well as with a gas supply means 22 which is composed of a gas cylinder, a mass flow controller, a stop valve and the like through a gas introduction pipe 10.

The opposite electrode 2 comprises: a gas distribution mechanism; a cooling jacket (cooling mechanism) 5 having a number of gas passages 5a; and a gas plate 6 having a number of gas outlets 6a which are communicated with gas passages 5a. These are placed in and fixed to a cylindrical frame body 3. A coolant channel 5b is formed in cooling jacket 5. A coolant is supplied from an introduction pipe 5c to coolant channel 5b through a pipe installed in, e.g., frame 3, and is discharged through a discharge pipe 5d. Here, the gas distribution mechanism which is provided with one or more gas distribution plates 4 having a number of small holes 4a is preferably employed.

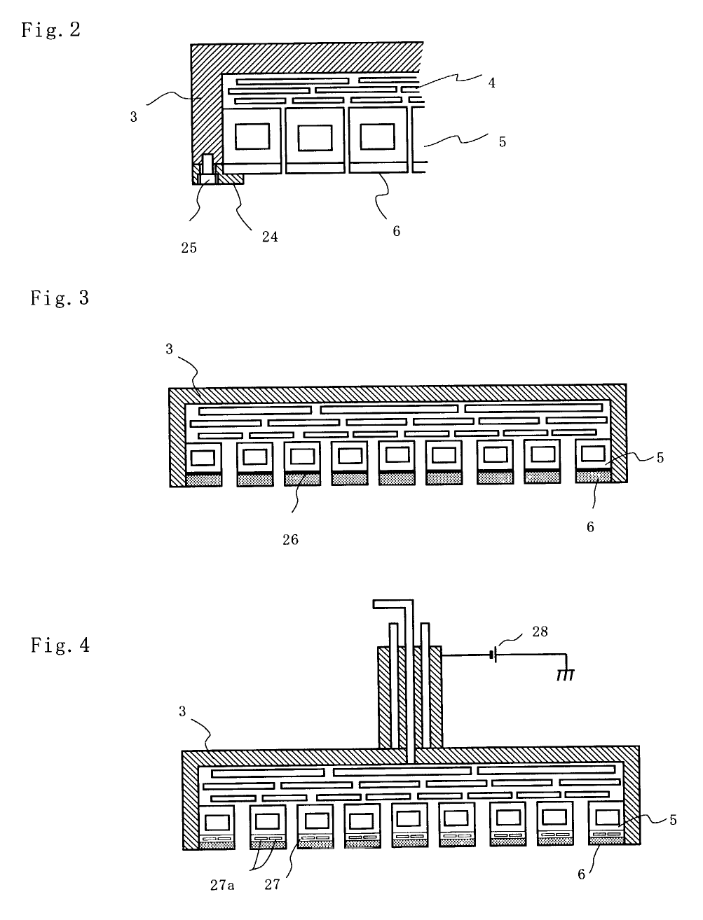

FIG. 2 is an enlarged view showing a fixing method of gas plate 6, where gas plate 6 directly comes in contact with cooling jacket 5 and is fixed by a clamping mechanism, which is composed of an annular fastener 24 and screws 25. Such clamping mechanism enables it to fix gas plate 6 all around. The gas plate 6 can be pressed and fixed uniformly to cooling jacket 5 with higher pressure, unlike the prior art where the gas plate is fixed by pressing parts of gas plate with tightening screws. Thus, this improves the cooling efficiency as a result of the increase in heat transfer, and avoids breakage of gas plate 6 when pressed. It is also possible to avoid the deterioration of etching processing characteristic due to the impurity contamination and the clogging of gas outlets, which often takes place when a brazing or adhesive is used for fixing.

The process gas that is supplied to the opposite electrode through gas introduction pipe 10 flows through small holes 4a of gas distribution plate 4 to spread uniformly insides the gas distribution mechanism, then passes through gas passages 5a of cooling jacket 5, and flows out of gas outlets of gas plate 6 to the inside of process chamber 1.

As mentioned above, gas distribution plate 4, cooling jacket 5, and gas plate 6 are arranged in this order from the upper stream to construct the opposite electrode. Furthermore, gas plate 6 is in direct contact with cooling jacket 5 and is pressed to be fixed with uniform force. This configuration enables it to make process gas uniformly flow towards substrate 40 and cool gas plate 6 efficiently and uniformly.

That is, since the process gas flows out uniformly toward the substrate from a number of gas outlets of the gas plate, the concentration of activated species which etches a substrate surface becomes uniform, making the etching rate and the shape of contact holes uniform over the whole substrate surface. Moreover, even for the processing conditions in which high RF electric power is supplied to opposite electrode 2 or substrate holding electrode 7, it is possible to effectively suppress the temperature rise of gas plate, and to prevent the decrease in etching rate due to the deposition of substances having a low melting point on substrate and the etching failure of contact holes or the like.

There is installed substrate holding electrode 7 on which an electrostatic chuck 9 is installed and in which a coolant channel 8 is provided. A coolant is introduced through introduction pipe 8a, and is discharged through exhaust pipe 8b. The substrate is cooled to a predetermined temperature with this coolant through the electrostatic chuck. The substrate holding electrode 7 is connected to a second high frequency power source 15 for bias control of substrate, and a DC power source17 for substrate electrostatic chucking. Between the power sources and substrate holding electrode 7, a blocking condenser 16 and a high frequency cut filter 18 are installed to prevent the mutual interaction between two power sources.

Furthermore, holes 20 are formed in substrate holding electrode 7. Ejector pins 19 are mounted inside the holes to move a substrate up and down when the substrate is transferred. The inside of hole is separated from the atmosphere with a bellows 21 and a plate 21a. The ejector pin 19 is fixed on plate 21a.

The etching processing using the apparatus of FIG. 1 is carried out as follows. The plate 21a of bellows 21 is pushed up with a driving mechanism to lift ejector pins 19 up. In this state, a robot hand holding a substrate is inserted through a gate valve (not illustrated) to place the substrate on ejector pins 19. The pins are moved down to place substrate 40 on electrostatic chuck 9, and then a predetermined electrical voltage is applied from DC power source 17 to electrostatically chuck the substrate.

Subsequently, process gas is supplied into process chamber 1 from the gas supply system 22 through the gas introduction pipe 10 and opposite electrode 2, and the pressure is set at a predetermined value. The high frequency electric powers of VHF band (for example, 60MHz) and of HF band (for example, 1.6MHz) are fed to opposite electrode 2 and substrate holding electrode 7 from first and second high frequency power sources 14, 15, respectively. The high-density plasma is generated by the high frequency electric power of VHF band, producing activated species, which etches substrate surface. In constract, the energy of ions is controlled independently of plasma density by the high frequency electric power of HF band. That is, any etching characteristic may be obtained by appropriately selecting two high frequency electric powers.

When such etching processing is repeatedly carried out, the temperature of the gas plate will gradually increase to equilibrium and the etched pattern will also vary, as mentioned above. However, since the efficiency to cool the gas ejection mechanism is improved in this embodiment, the number of processing can be reduced till the gas plate reaches thermal equilibrium. For example, in the case of 0.13 μm pattern, the number of processing was about 10 times until the stable etching characteristic was obtained after the processing started. Moreover, the temperature distribution of the gas plate became more uniform, improving the uniformities of etching rate and contact hole configuration over the whole substrate.

That is, by employing the apparatus shown in FIG. 1, it becomes possible to accomplish simultaneously both the uniform gas flow distribution and the efficient cooling of the gas plate, which enables it to carry out etching processing of finer pattern with stability and high productivity.

In this invention, the gas outlet of 0.01-1 mm in diameter is desirable, and that of 0.2 mm or less is preferable. In this range, it is easier to control the gas flow distribution and eject gas more uniformly out of gas outlets. The thickness of the gas plate is usually 1.0-15.0 mm.

Moreover, the positions of gas passage 5a of the cooling jacket and gas outlet 6a of the gas plate may be deviated from each other to decrease the conductance, whereby the flow rate is reduced and the plasma is restrained from penetrating into the electrode. This method is preferably adopted when it is difficult to form small holes in the gas plate. The hole size of gas passage is usually 1.0-3.0 mm.

The diameter of holes 4a of gas distribution plate 4 is 0.1-3.0 mm. Here, the diameter and the number (density) of holes are preferably selected so as to make the pressure gradient small over the whole gas distribution plate and be suited to this gradient, whereby more uniform gas ejection can be realized.

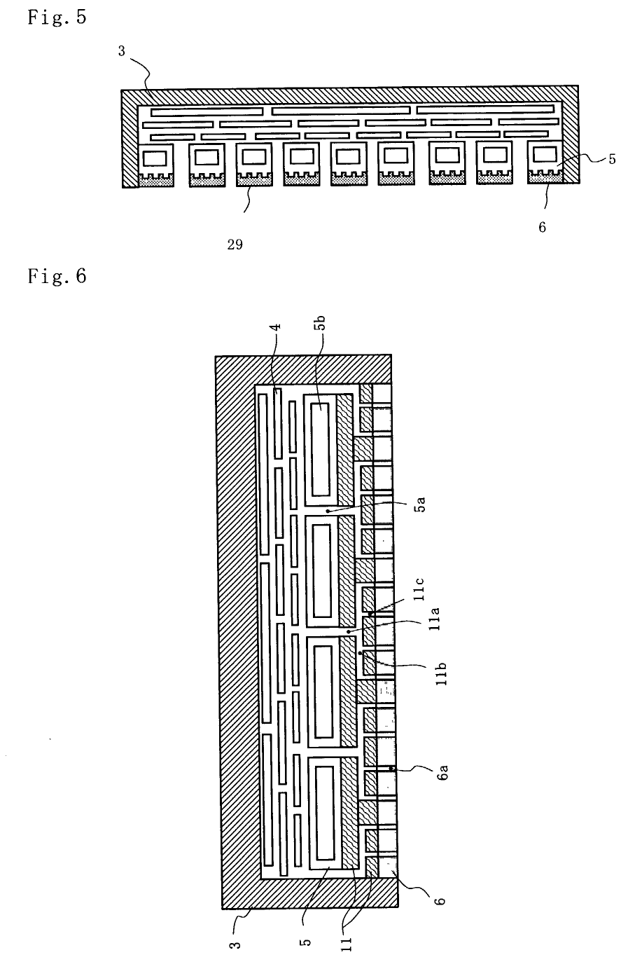

Next, other examples of this embodiment are shown in FIGS. 3-5.

The gas plate 6 and cooling jacket 5 are in direct contact with each other in FIG. 1. However, a heat conductive sheet, which is flexible and highly heat conductive, may be placed between them as shown in FIG. 3. By placing such a heat conductive sheet, the sheet enters into microscopic roughness by pressure to increase the substantial contact area and improve the heat transfer rate. A sheet with a thickness of 10-500 μm of metal such as indium or polymer such as silicon resin and conductive rubber is used for the heat conductive sheet.

An electrostatic chucking mechanism is installed in FIG. 4 instead of the gas plate clamping mechanism of FIG. 1. Here, electrostatic chuck 27 constructed by arranging dipole electrodes 27a in a dielectric is installed on cooling jacket 5. A predetermined voltage is applied to dipole electrodes 27a from a power source 28 to electrostatically chuck the gas plate. Since the whole gas plate can be uniformly pressed by using the electrostatic chuck, the cooling efficiency and its uniformity are further improved. Moreover, it is easier to exchange the gas plate. Any type of electrostatic chuck can be also used other than those with the dipole electrodes.

On both surfaces of gas plate 6 and cooling jacket 5 of the gas ejection mechanism shown in FIG. 5, there is formed the ruggedness 29 that is engaged with each other to increase contact area and to improve the heat conduction. The engagement of ruggedness prevents the gas plate from bending even when the gas plate is partially heated to bend. The bending stress works to increase the contact area and the pressure at the engaged portions, which increases the heat transfer. Therefore, it is possible to prevent the prior art disadvantage, in which gaps are generated due to the bend of gas plate and as a result the temperature thereof further rises to decrease the temperature uniformity. In the above-mentioned embodiments, the gas distribution mechanism has a configuration that one or more gas plates are installed in the space over the cooling jacket. However, the gas distribution plate is not always required in this invention. That is, the gas distribution mechanism where only the space is provided between the gas introduction pipe and the cooling jacket can also be employed in this invention.

The second embodiment of this invention is shown in FIG. 6. A gas ejection mechanism of this embodiment is constructed in such a manner that first gas distribution mechanism comprising one or more of gas distribution plates, cooling jacket 5, second gas distribution mechanism 11, and gas plate 6 are arranged in this order from the upper stream. The second distribution mechanism is arranged in this embodiment, which is different from the first embodiment. The arrangement of the second gas distribution mechanism between cooling jacket 5 and gas plate 6 makes it possible to enlarge the coolant channel (i.e., to increase the cooling capacity) as well as to provide gas outlets under the coolant channel 5b in order to make gas flow distribution more uniform.

The second gas distribution mechanism 11 is fabricated by, for example, bonding with silver solder or indium a first disk in which a number of small holes 11a are formed corresponding to gas passages Sa of cooling jacket 5 to a second disk in which small holes 11c corresponding to gas outlets 6a of gas plate 6 and branching hollow portions 11a for making gas that is supplied through gas passages 5a flow to small holes 11c are formed. The second distribution mechanism is pressed with uniform force over the whole surface and fixed with e.g., a number of screws onto the cooling jacket.

With such configuration, a larger coolant channel can be formed. In addition, gas outlets can be formed with high density (preferably more than 1.0/cm2). Therefore, not only can the high cooling efficiency be obtained, but the uniformity of gas flow distribution can also be maintained.

Furthermore, only the second disk mentioned above may be used as second gas distribution mechanism. The second distribution mechanism can also be fixed with brazing or bonding instead of screws.

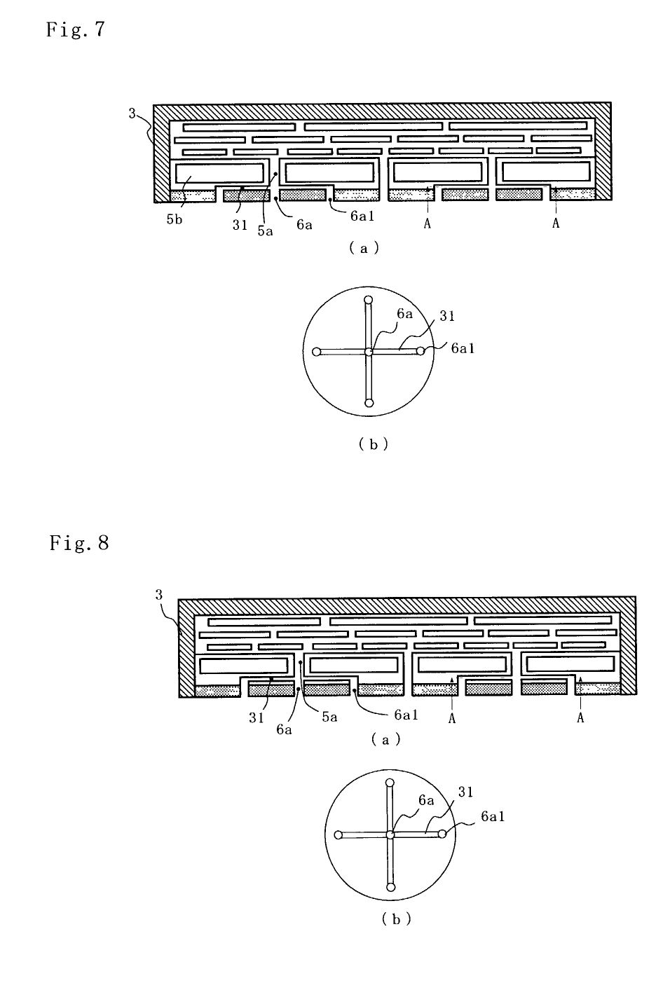

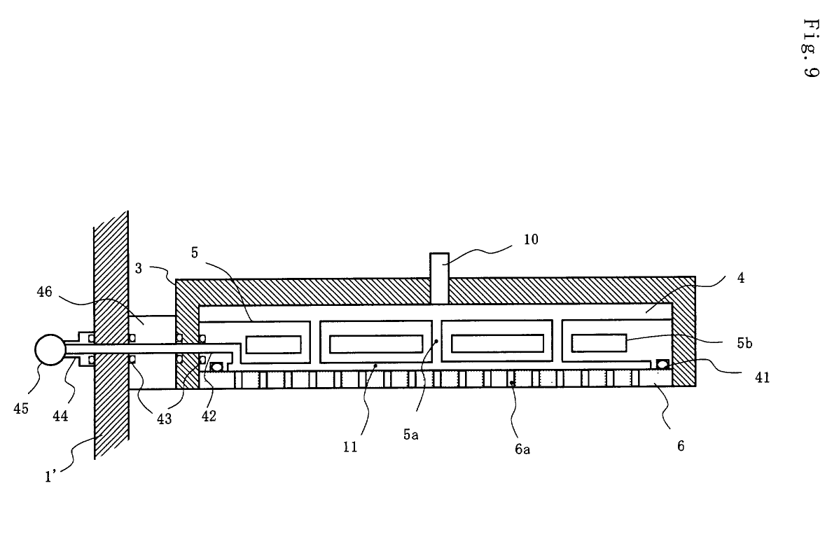

In the embodiment, the second gas distribution mechanism is prepared separately from the cooling jacket. However, it is also possible to form gas distribution mechanism in the cooling jacket itself. This example is shown in FIGS. 7 and 8.

FIG. 7(a) and 7(b) are a cross-sectional view and a view taken along A-A line showing a gas ejection mechanism, respectively.

Gas branch grooves 31 are formed in the cooling jacket so that gas outlets 6a1 formed under coolant channel 5b are communicated with gas passages 5a in the example of FIG. 7. That is, the configuration that gas outlets are also provided under coolant channel 5b is employed.

By communicating gas passage 5a with a plurality of gas outlets 6a1 through branch groove 31, that is, by forming branch grooves on the cooling jacket surface in contact with the gas plate so that gas is introduced from one gas passage 5a into a plurality of gas outlets 6a, 6a1, gas outlets 6a1 can be provided just under the coolant channel. Thus, The gas flow uniformity and the cooling efficiency are simultaneously improved.

When the difference of conductance or gas ejection rate may occur between gas outlets 6a under gas passage 5a and outlets 6a1 communicated with branch groove 31 (i.e., gas outlets under the coolant channel), the outlets under gas passage 5a may be made smaller or removed, whereby the gas flow can be made uniform over the whole gas plate.

Here, the width of gas branch groove 31 is preferably about 0.1-2 mm from viewpoints of uniform gas flow formation and cooling efficiency.

In the example of FIG. 8, branch passages 31 of gas passages are formed insides the cooling jacket and connected with gas outlets 6a1.

With such configuration, the cooling efficiency is further improved as compared with FIG. 7. The cooling jacket can be fabricated by, for example, bonding to unite a part where coolant channel 5b and gas passages 5a are formed, and parts where gas outlets 6a, 6a1 and gas branch grooves 31 are formed with brazing such as silver solder, a flexible and low melting-point metal such as indium or a solder.

In addition, although the heat transfer is reduced, a heat-conductive polymer rubber or a rubber containing fibrous metal may be placed between them or may be used as an adhesive.

The third embodiment of this invention will be explained using FIG. 9. In this embodiment, the gas plate side surface of cooling jacket 5 is cut to form a disk shaped space as a second gas distribution mechanism 11, so that the heat transfer through the process gas is made use of in addition to the heat conduction between the gas plate and the cooling jacket.

To achieve this object, the height of the second distribution mechanism (disk shaped space) 11 is preferably set to 0.1mm or less, and the internal pressure is preferably adjusted to 100 Pa or higher. Thus, the heat transfer with the process gas between cooling jacket 5 and gas plate 6 can be greatly increased, which further improves the efficiency to cool the gas plate. The pressure of about 10 kPa is usually adopted as a upper limit although higher pressure is available so long as the mechanism has enough mechanical strength to stand the pressure. In particular, the pressure of 2-4 kPa is preferably adopted.

Thus, since the pressure in second distribution mechanism 11 becomes high compared with that of process chamber 1, a sealing member 41 such as 0-ring is preferably arranged to suppress the gas leak between cooling jacket 5 and gas plate 6. In order to measure the pressure in second distribution mechanism 11, the above-mentioned space 11 is communicated with a pressure gauge 45 through, e.g., passage 42 which penetrates water cooling jacket 5, frame member 3, insulator 46, process chamber wall 1′, and connecting member 44. There are arranged O-rings 43 between members. However, it is also possible to obtain the pressure in the second distribution mechanism from the supply gas pressure based on the experimental or calculated relationship between the internal pressure of second distribution mechanism and the supply gas pressure.

Although the second distribution mechanism is made by cutting the surface of cooling jacket as mentioned, it is also made by placing a ring-like disk on the circumference part of cooling jacket surface. Moreover, the space is not restricted to a disk shape and therefore may have the configuration in which the gas plate is partially in contact with the cooling jacket therein.

In the embodiments mentioned so far, non-metal material such as Si, SiO2, carbon, or the like is preferably used as material of gas plate 6. These materials are difficult to be processed and easy to break down. However, in the embodiments as mentioned above, there is no need to form gas distribution grooves in gas plate 6 itself, and therefore the damage during installation or due to thermal hysteresis during processing can be avoided. The gas plate may be processed as long as it is possible, though.

In the case where e.g., silicon oxide is etched, the gas plate is preferably made from scavenger material such as Si, which consumes fluorine radicals generated during processing and prevents the reduction of photoresist width. This makes it possible to carry out etching processing of finer patterns.

Furthermore, there is no special limitation in coolant; for example, water and Fluorinert (trademark) are used. In addition, the simultaneous cooling using a coolant and a heat conductive gas such as He is also preferably adopted to cool the substrate in etching processing.

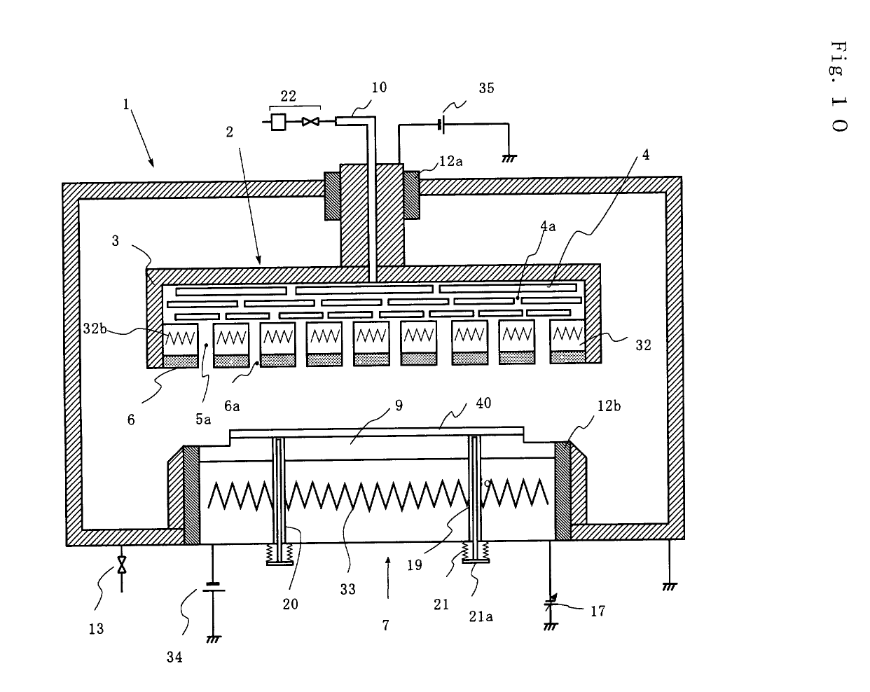

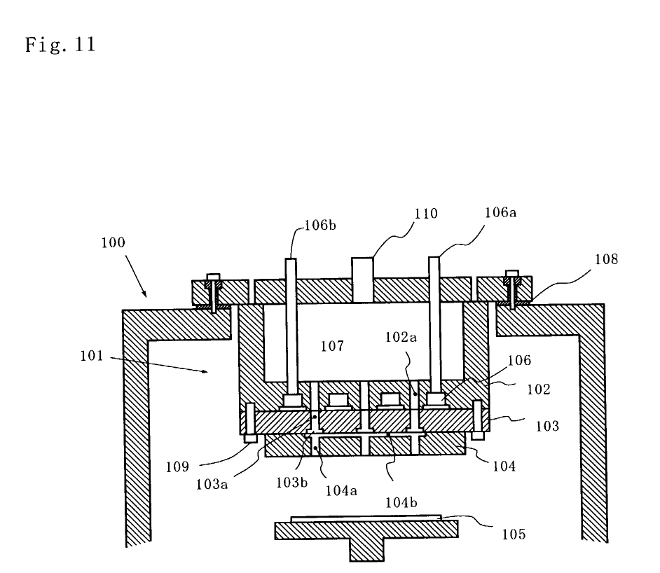

The gas ejection mechanism of this invention described above can also be applied to various surface processing apparatuses such as a plasma CVD apparatus, an ashing apparatus, a thermal CVD apparatus and the like as well as a etching apparatus. A thermal CVD apparatus is shown in FIG. 10 as the fourth embodiment of this invention.

FIG. 10 is a cross-sectional view of a thermal CVD apparatus, in which a heating mechanism is arranged both in a gas ejection mechanism and a substrate holding mechanism. Here, the explanation of the same mechanism as in the first embodiment may be omitted.

The gas ejection mechanism 2 is composed of a gas distribution mechanism 4, a heating mechanism 32 in which a heater 32b is incorporated, and a gas plate 6 being fixed by the clamping mechanism shown in FIG. 2. An electrostatic chuck 9 is attached on the top of and a heater 33 such as resistor is incorporated in a substrate holding mechanism 7. A substrate 40 is heated to a predetermined temperature by supplying an electric current to the heater 33 from a power source 34.

The process gas is introduced in the same manner as in the first embodiment and the electric power is supplied to heater 32b of heating mechanism 32 from power source 35 for heater. The gas plate 6 is heated uniformly and efficiently to uniformly eject a process gas that is appropriately decomposed by heat from gas outlets 6a, which makes it possible to form a uniform film with high quality.

The shapes and materials of gas plate, gas passage, first and second gas distribution mechanisms explained in FIGS. 1-9 are also applied to a thermal CVD apparatus. However, the material to be selected should be enough heat resistant at the heating temperature.

The parallel-plate type surface processing apparatuses have been explained so far. In this invention, a gas ejection mechanism may have various shapes such as dome, cylinder, rectangular, a polygonal prism, polygonal pyramid, cone, truncated cone, truncated polygonal pyramid, and round shape.

As has been mentioned, a gas ejection mechanism of this invention enables it to make gas uniformly flow out of gas outlets of gas plate and to cool or heat the gas plate uniformly and efficiently. For this reason, the bending or the crack of gas plate due to heat can be prevented. Furthermore, in the case of etching processing, etching rate, resist selection ratio, the selection ratio inside the hole, and the etched shape of contact hole can be made uniform over the whole substrate. It is also possible to realize uniform process rate in the cases of thermal CVD, plasma CVD, or ashing processing.

1. A surface processing apparatus comprising: a process chamber in which a substrate holding mechanism holding a substrate and a gas ejection mechanism are arranged to face each other; an exhaust means for exhausting the inside of said process chamber; and a gas supply means for supplying a gas to the said gas ejection mechanism; to process the substrate with the gas introduced into said process chamber through said gas ejection mechanism,
wherein a gas distribution mechanism communicated with said gas supply means, a cooling or the heating mechanism provided with a coolant channel or a heater to cool or heat a gas plate and a number of gas passages communicated with said gas distribution mechanism, and said gas plate having a number of gas outlets communicated with said gas passages are arranged from the upper stream to construct said gas ejection mechanism, and
wherein said gas plate is fixed to said cooling or heating mechanism with a clamping member which clamps the periphery of said gas plate or with an electrostatic chucking mechanism.

2. The surface processing apparatus according to claim 1, wherein said gas ejection mechanism is connected with a high frequency power source so that a plasma is generated to carry out processing by feedng high frequency electric power to said gas ejection mechanism.

3. The surface processing apparatus according to claim 1, wherein the diameter of said gas outlet is 0.01-1 mm

4. The surface processing apparatus according to claim 1, wherein the ruggedness is formed on contact surfaces of said gas plate and said cooling or heating mechanism to engaged with each other.

5. The surface processing apparatus according to claim 1, wherein said gas plate is fixed to said cooling or heating mechanism through a flexible heat conductive sheet.

6. The surface processing apparatus according to claim 1, wherein said gas plate comprises Si, SiO2, SiC, or carbon.

7. A surface processing apparatus comprising:
a process chamber in which a substrate holding mechanism holding a substrate and a gas ejection mechanism are arranged to face each other;
an exhaust means for exhausting the inside of said process chamber; and a gas supply means for supplying a gas to the said gas ejection mechanism; to process the substrate with the gas introduced into said process chamber through said gas ejection mechanism,
wherein a first gas distribution mechanism communicated with said gas supply means, a cooling or a heating mechanism provided with a coolant channel or a heater to cool or heat a gas plate and a number of gas passages communicated with said first gas distribution mechanism, a second gas distribution mechanism, and said gas plate having a number of gas outlets which are more than said gas passages are arranged from the upper stream to construct said gas ejection mechanism, and said gas passages are communicated with said gas outlets through said second gas distribution mechanism, and
wherein said gas plate is fixed to said cooling or heating mechanism with a clamping member which clamps the periphery of said gas plate or with an electrostatic chucking mechanism.

8. The surface processing apparatus according to claim 7, wherein said gas outlets are formed in the said gas plate under said coolant channel or said heater.

9. The surface processing apparatus according to claim 7, wherein said second gas distribution mechanism has a space with a height of 0.1 mm or less, and the pressure in said space is set to 100 Pa or higher.

10. The surface processing apparatus according to claim 8, wherein said second gas distribution mechanism has a space with a height of 0.1mm or less, and the pressure in said space is set to 100 Pa or higher.

11. The surface processing apparatus according to claim 7, wherein said gas ejection mechanism is connected with a high frequency power source so that a plasma is generated to carry out processing by feeding high frequency electric power to said gas ejection mechanism.

12. The surface processing apparatus according to claim 8, wherein said gas ejection mechanism is connected with a high frequency power source so that a plasma is generated to carry out processing by feeding high frequency electric power to said gas ejection mechanism.

13. The surface processing apparatus according to claim 7, wherein the diameter of said gas outlet is 0.01-1 mm

14. The surface processing apparatus according to claim 8, wherein the diameter of said gas outlet is 0.01-1 mm.

15. The surface processing apparatus according to claim 7, wherein the ruggedness is formed on contact surfaces of said gas plate and said second gas distribution mechanism to engaged with each other.

16. The surface processing apparatus according to claim 8, wherein the ruggedness is formed on contact surfaces of said gas plate and said second gas distribution mechanism to engaged with each other.

17. The surface processing apparatus according to claim 7, wherein said gas plate is fixed to said second gas distribution mechanism through a flexible heat conductive sheet.

18. The surface processing apparatus according to claim 8, wherein said gas plate is fixed to said second gas distribution mechanism through a flexible heat conductive sheet.

19. The surface processing apparatus according to one of claim 7, wherein said gas plate comprises Si, SiO2, SiC, or carbon.

20. The surface processing apparatus according to one of claim 8, wherein said gas plate comprises Si, SiO2, SiC, or carbon.
